(19) United States
(12) Patent Application Publication
(10) Pub. No.: US 2010/0289778 A1
(43) Pub. Date: Nov. 18, 2010

(54) CONTROL DEVICE

(75) Inventors: Filiberto Felici, Dogana (SM); Gilberto Monaldini, Torriana (IT); Mauro Gasparini, Viserba di Rimini (IT); Paolo Pecchenini, Cassano Magnano (IT)

Correspondence Address: LAUBSCHER & LAUBSCHER, P.C., 1160 SPA ROAD, SUITE 2B, ANNAPOLIS, MD, 21403, US

(73) Assignee: ROBOPAC S.A., Falciano E6 (SM)

(21) Appl. No.: 12/671,087

(22) PCT Filed: Jul. 29, 2008
(86) PCT No.: PCT/IB2008/001968

§ 371 Date: Jul. 2, 2010

(30) Foreign Application Priority Data
Jul. 31, 2007 (IT) MO2007A000257

(51) Int. Cl. H03K 17/94; G06F 3/033; G08B 23/00

(52) U.S. Cl. 345/184; 341/35; 340/500

(57) ABSTRACT

A control device that is associable with a machine, in particular a wrapping machine, includes a panel provided with a selecting device for selecting and setting operating parameters of the machine. The selecting device includes a knob that is rotatable around an axis and is fixed to the panel. In accordance with a method for setting operating parameters of a machine, in particular a wrapping machine, a control device provided with a knob rotating around an axis sets operating parameters by rotating the knob around the axis.

The invention relates to a control device for operating machines, in particular a control device owing to which it is possible to set and adjust operating parameters of a wrapping machine.

Control devices or panels are known owing to which it is possible to set operating parameters of a wrapping machine by means of a plurality of selecting pushbuttons to be selected, each of which enables a determinate parameter of the wrapping machine to be selected. In order to enable the operator to identify the selecting pushbutton associated with the parameter to be set, on each selecting pushbutton an image or symbol is provided that schematically shows the parameter with which the pushbutton is associated.

Once the parameter to be set has been chosen, the operator assigns a value to this parameter by means of a pair of pushbuttons, for example marked by a “plus” and by a “minus”. The operator increases the value of the selected parameter by pressing the pushbutton marked by the “plus” sign and on the other hand decreases the value of the selected parameter by pressing the pushbutton marked by the “minus” sign.

The operator then confirms the value assigned to the parameter by pressing the selecting pushbutton a second time.

A drawback of such known panels is that they have significant overall dimensions as with each parameter there is associated a corresponding selecting pushbutton. Further, in order to maintain limited overall surface dimensions of the panel, the dimensions of each selecting pushbutton are small and therefore also the images or symbols represented thereupon are of small dimensions. In this case, the operator could have problems in recognising the desired selecting pushbutton due to the difficulty in reading the images. Further, this panel is expensive as the pushbuttons have to be supported by an electronic card having dimensions that are equal to that of the surface occupied by the set of pushbuttons.

A further drawback of such panels consists of the fact that the operation thereof is sometimes difficult to understand because of the great number of pushbuttons provided. An object of the invention is to improve the control devices, in particular the control devices associable with a wrapping machine for setting operating parameters of the wrapping machine.

Another object is to provide a control device that is easy, immediate and intuitive to use, also by non-specialised and non-expert staff.

A further object is to obtain a control device having particularly small and compact dimensions and precise and reliable operation.

In a first aspect of the invention, there is provided a control device associable with a machine, in particular a wrapping machine, comprising panel means provided with selecting means for selecting and setting operating parameters of said machine, characterised in that said selecting means comprises knob means rotatable around an axis and fixed to said panel means.

In a second aspect of the invention, there is provided a method for setting operating parameters of a machine, in particular a wrapping machine, by a control device provided with knob means rotating around an axis, comprising selecting an operating parameter to be set, characterised in that said selecting comprises rotating said knob means.

Owing to these aspects of the invention it is possible to reduce significantly the number of pushbuttons provided on the panel means. Owing to the knob means the operator is, in fact, able to select the desired operating parameter. In this manner, it is no longer necessary to provide a single pushbutton for each operating parameter and the control device thus has a smaller dimension than known control devices.

The knob means is further able to adjust a value to be assigned to the selected parameter. In particular, after confirming selection of the operating parameter to be set, the control device assumes an adjusting configuration in which, by further rotating the knob means, a value to be assigned to this parameter can be adjusted. In this case, the control device has even smaller overall dimensions as by the knob means alone it is possible to select the desired operating parameters and adjust the value to be assigned to the parameters without the need for adjusting pushbuttons. The reduced dimensions of the knob means and the absence of pushbuttons allow to have greater space on the control panel to insert representative figures of the operating parameters having greater dimensions and clearer and more precise details. The device of the invention thus enables even a non-specialised and non-expert user to set the operating parameters of the wrapping machine in an easy, immediate and intuitive manner.

The invention may be better understood and implemented with reference to the attached drawings, which illustrate an embodiment thereof by way of non-limiting example, in which:

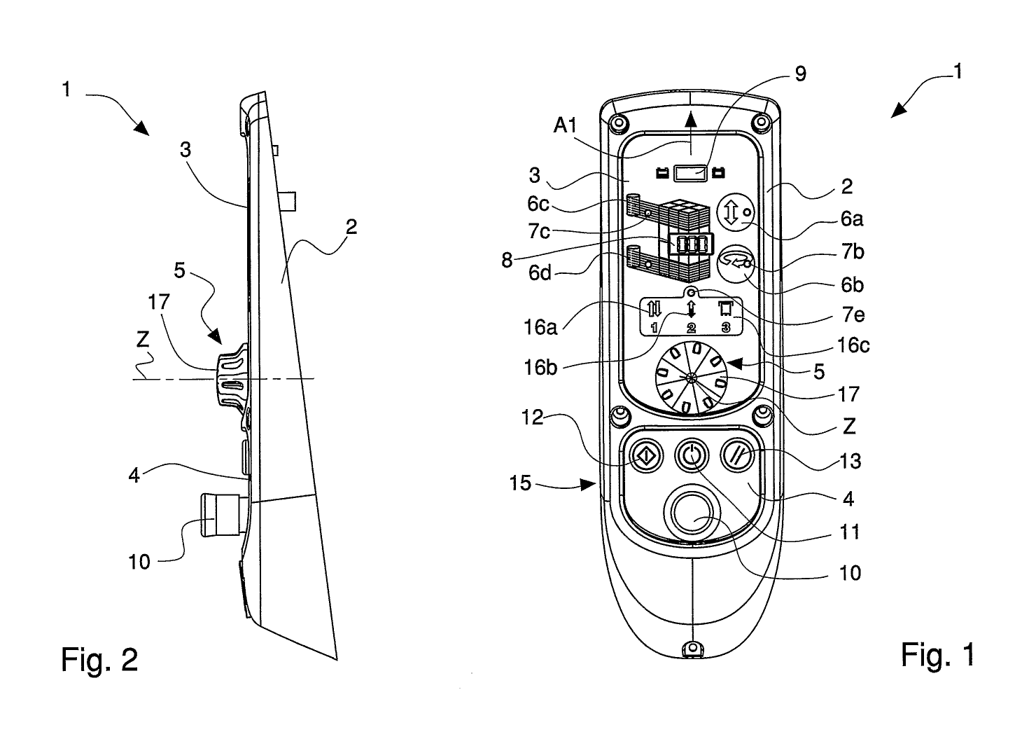

FIG. 1 is a frontal view of the control device of the invention;

FIG. 2 is a side view of the device in FIG. 1;

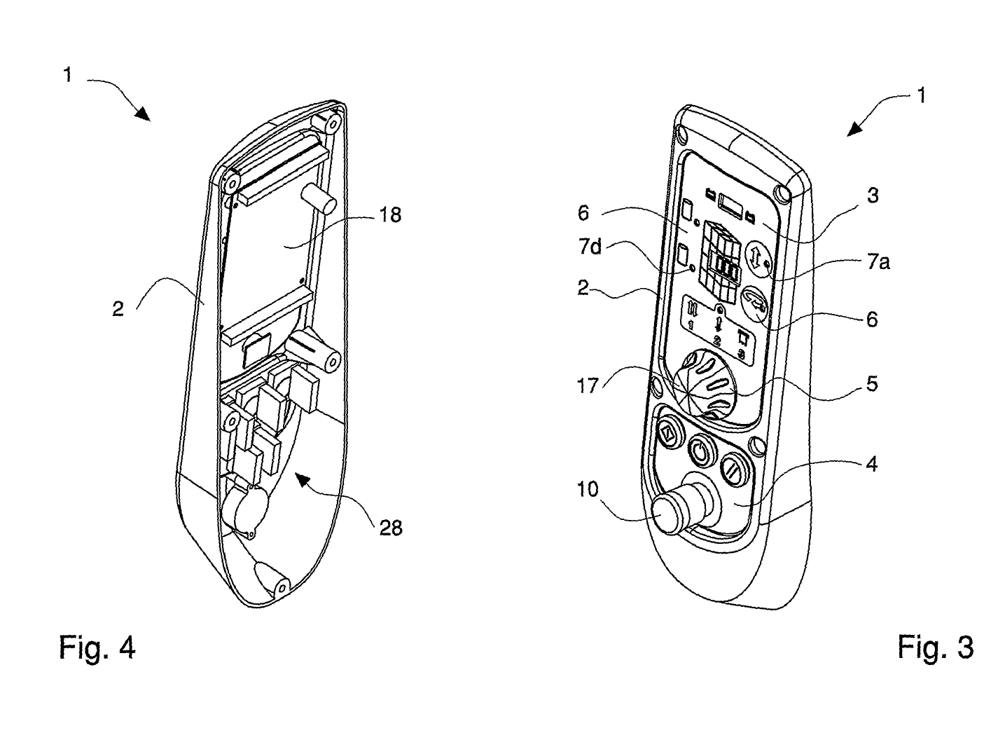

FIG. 3 is a perspective front view of the device in FIG. 1;

FIG. 4 is a perspective rear view of the device in FIG. 1;

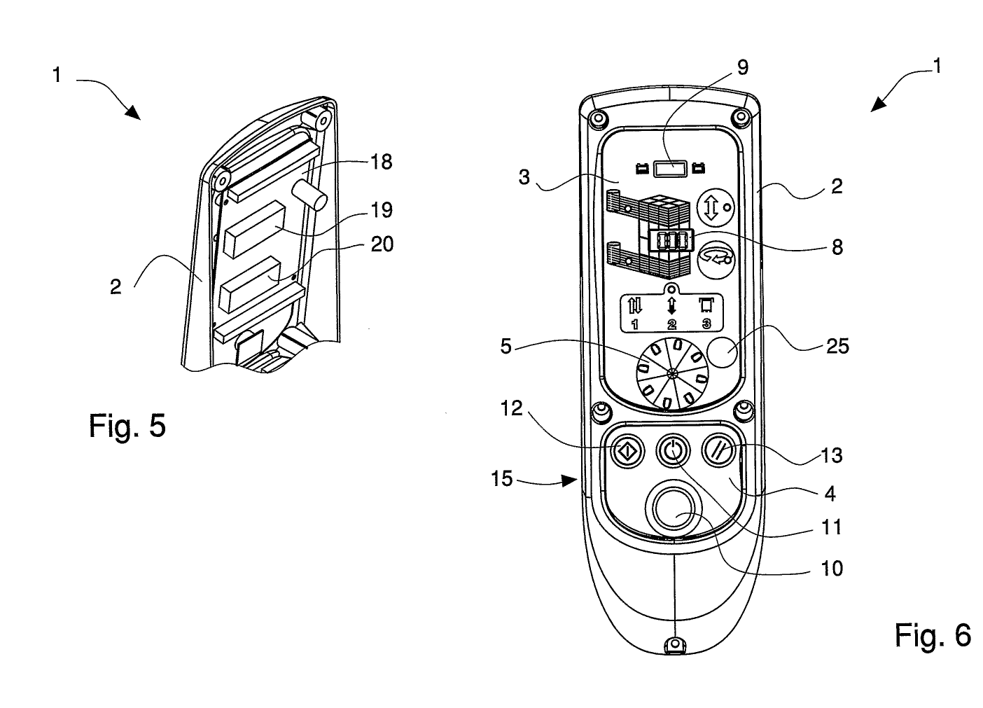

FIG. 5 is a perspective rear view of another embodiment of the device in FIG. 1;

FIG. 6 is a front perspective view of a further embodiment of the device in FIG. 1;

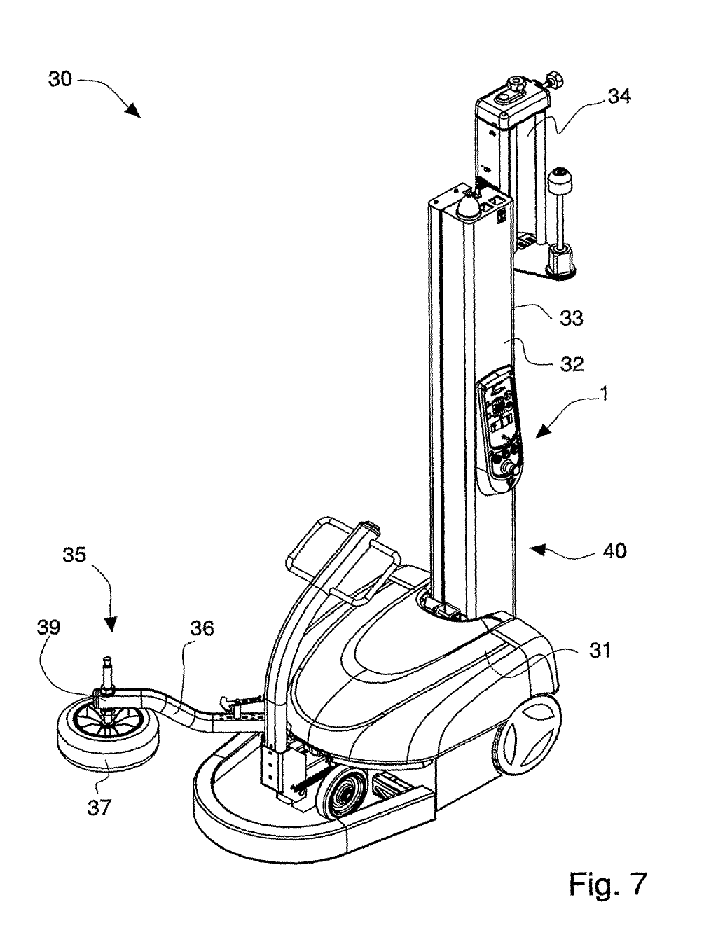

FIG. 7 is a perspective view of a wrapping machine with which the control device of the invention is associated.

With reference to FIGS. 1 to 3, there is illustrated a control device 1 arranged for setting operating parameters of a machine, for example a wrapping machine, associated therewith and for controlling the machine.

The control device 1 is substantially a panel provided with selecting or control means 5 which enables an operator to interact with the machine, i.e. with a control unit of the machine, for example an industrial computer or programmable logic controller (PLC).

The device 1 comprises panel means 2 having an elongated shape along a direction A1 and comprising a first square 3 and a second square 4 arranged, for example, upstream of the first square 3 according to the direction A1.

On the first square 3 the control means is arranged comprising a knob 5 that has a substantially cylindrical shape having a Z axis. The knob 5 is rotatably supported by the panel means 2 so as to be able to be rotated by an operator around the axis Z clockwise or anticlockwise.

The knob 5 comprises a surface 17, arranged substantially perpendicularly to the axis Z. The knob 5 can be further pressed by the operator on the surface 17 according to a direction that is substantially parallel to the axis Z, by acting substantially like a pushbutton.

Alternatively, the knob 5 can be pressed along a direction that is transverse, in particular orthogonal, to the axis Z. The rotation of the knob 5 enables the operating parameters of the machine to be selected and the values of the operating parameters to be adjusted, respectively in a selecting mode and in an adjusting mode of said device 1. By pressing the knob 5 it is possible to confirm the selection of a desired operating parameter and access the adjusting mode of the values of the operating parameters. In this mode, by further pressing the knob 5 it is possible to confirm the selection of a modified value, i.e. store and/or send to the control unit of the machine this set value of the operating parameter. At the same time it is possible to return to selecting mode.

In an embodiment of the control device 1 illustrated in FIG. 6, the knob 5 is not pressible but only rotatable and confirming pushbutton means 25 is provided for selecting an operating parameter and accessing the adjusting mode and for storing a set value and returning to selecting mode.

In the first square 3 is arranged a plurality of figures or symbols 6a, 6b, 6c, 6d, each of which is associated with a respective operating parameter of the machine. In particular, each FIGS. 6a, 6b, 6c, 6d represents schematically the associated operating parameter so that the operator can easily recognise the operating parameter. With each FIGS. 6a, 6b, 6c, 6d there is associated a respective warning light 7a, 7b, 7c, 7d, 7e.

In the centre of the first square 3 there is further arranged a luminous display 8 that is suitable for displaying a set value for each operating parameter.

In the first square 3 there is provided a further display 9 that continuously displays the value of a particular operating parameter of the machine, for example the supply status of the machine, in the specific case the charge of battery means that supplies said machine.

In the second square 4 there is arranged a plurality of operating pushbuttons 15.

The operating pushbuttons 15 comprise, for example, an emergency pushbutton 10, a switch-on pushbutton 11, a start pushbutton 12 and a recovery or reset pushbutton 13.

When the emergency pushbutton is pressed, it stops the machine.

The switch-on pushbutton 11, arranged downstream of the emergency pushbutton 10 according to the direction A1 when it is pressed, switches on the machine.

The start pushbutton 12, arranged alongside the switch-on pushbutton 11 when pressed after the switch-on pushbutton 11, causes the machine to start up.

The reset pushbutton 13, arranged alongside the switch-on pushbutton 11, on the opposite side to the start pushbutton 12 is pressed by the operator after the emergency pushbutton 10 to enable the machine to be started up again. The control device 1 comprises an electronic control card 18, shown in FIG. 4, to which the knob 5 and the warning lights 7a, 7b, 7c, 7d, 7e are connected. This electronic control card 18 supports and enables the operation of the knob and warning lights and, at the same time, sends the values of the operating parameters set by the operator to the control unit or PLC of the machine, to enable the operation of the machine. Similarly, the operating pushbuttons 15 are provided with a respective electronic card 28 by means of which operating pushbuttons 15 are connected to said control unit.

The electronic control card 18 and the control unit of the machine are distinct and separate.

The electronic control card 18 may comprise storage means for storing set values of said operating parameters. In an embodiment of the device that is not illustrated in the figures, the electronic control card 18 and the control unit or PLC 19 are on the other hand integrated into a single circuit fixed to the panel means 2 of the device 1. In a further embodiment of the control device 1 of the invention illustrated in FIG. 5, there is provided that the electronic control card 18 comprises, in addition to the PLC 19, a power or drive card 20, arranged for driving and controlling motors, actuators and power devices located in the machine.

The machine controlled by the control device 1 may be of different types.

In the example shown in FIG. 5 the control device 1 is associated with a movable wrapping machine 30, a so-called wrapping robot, of known type.

This wrapping machine 30 is used for wrapping objects with a film of plastics that is extendible so that the product is not exposed directly to the external environment.

The wrapping machine 30 comprises a main body 31 comprising a motor, which is not shown, arranged for moving the wrapping machine 30. From the main body 31 a supporting column 32 with which a guide 33 is associated, extends along a vertical direction. Along the guide 33 a supporting carriage 34 can slide that supports a reel of extendible film.

The wrapping machine 30 comprises a positioning device 35 provided with a supporting rod 36 that projects from the main body 31 along a direction that is substantially transverse to the direction defined by the supporting column 32. The positioning device 35 comprises an abutting wheel 37 that is rotatably supported by an end 39 of the supporting rod 36.

During operation, the wrapping machine 30 rotates around the object to be wrapped, always being maintained at a defined distance from the product owing to the abutting wheel 37 that rotates on the side surface of the object. An end zone of the film is fixed to the object so that, during rotation of the wrapping machine 30 around the product, the film unwinds from the reel to wrap around the object. Further, still during rotation, the supporting carriage 34 slides along the guide 33 so that the entire side surface of the object is covered by the film.

The wrapping machine 30 comprises position sensors, which are not shown, which are able to indicate when the supporting carriage 34 reaches an upper end zone of the object, so that the supporting body 34 does not further continue along the guide 33 beyond the height of the upper end zone of the object.

In a central zone 40 of the supporting rod 32 is arranged the control device 1 owing to which it is possible to set a plurality of operating parameters of the wrapping machine 30.

Numerous operating parameters can be set by the operator. Each machine, and in particular each type of wrapping machine, can provide different operating parameters. In the example shown in the Figures, the control device 1 enables the operator to set five different operating parameters.

A first parameter, associated with FIG. 6a illustrating a double arrow shown in FIG. 1, defines the ascent and descent speed of the supporting carriage 34 along the guide 33.

A second parameter, associated with FIG. 6b illustrating a circular arrow shown in FIG. 1, defines the rotation speed of the wrapping machine 30 around the object.

A third parameter, associated with FIG. 6c illustrating a first roller that wraps an upper end zone of a parallelepipedon shown in FIG. 1, defines the number of rotations that the wrapping machine 30 has to perform around the upper end zone of the object.

A fourth parameter, similar to the third and associated with FIG. 6d illustrating a second roller that wraps a lower end zone of a parallelepipedon shown in FIG. 1, defines the number of rotations that the wrapping machine 30 has to perform around a lower end zone of the object.

A fifth parameter, associated with three lesser FIGS. 16a, 16b, 16c, establishes a work mode or programme on the basis of which the wrapping machine 30 has to proceed during wrapping of the object.

In particular, there is provided a first work mode, associated with a first FIG. 16a that represents two parallel and opposite arrows, in which during rotation of the wrapping machine 30 around the object the supporting carriage 34 performs a first stroke from the lower end zone to the upper end zone and subsequently a second stroke that is similar to the first stroke but with an opposite direction.

In a second work mode, associated with a second FIG. 16b that represents a single arrow, during rotation of the wrapping machine 30 around the object, the supporting carriage 34 runs the first stroke or the second stroke exclusively.

There is provided a third work mode, associated with a third FIG. 16c, which represents an object covered above by a sheet, in which, when the supporting carriage 34 reaches the upper end zone of the object, the wrapping machine 30 interrupts rotation to deposit on the upper surface of the object a protective sheet so that the object is also covered on this surface.

The operation of the control device 1 provides for the operator initially switching on the wrapping machine by pressing the switch-on pushbutton 11. Subsequently, the operator proceeds to select one of the operating parameters inasmuch as the control device 1 is arranged in the selecting configuration when is just switched-on. In this selecting configuration, the operator, by rotating the knob 5, selects the operating parameter which he desires to set. During the rotation of the knob 5, on the display 8 there can be displayed the numeric values of the operating parameters. Equally, during rotation the warning light of the parameter selected at that moment by rotating the knob 5, switches on.

When the operator has defined the desired parameter he presses the knob 5. In this manner the control device 1 moves from the selecting configuration to the adjusting configuration.

In this adjusting configuration, the warning light 7a, 7b, 7c, 7d, 7e associated with the selected operating parameter flashes. In the adjusting configuration the operator, by further rotating the knob 5, adjusts the numeric value to be assigned to the selected operating parameter or selects a work mode.

The numeric value of the parameter or of the work mode is displayed for greater clarity on the display 8. In order to confirm the selection of the value and store the value or send the value to the control unit 19 of the machine, the operator further presses the knob 5. In this manner, the control device 1 abandons the adjusting configuration to return to the selecting configuration.

The electronic control card 18 of the device 1 can be configured so that in the adjusting configuration, after a preset interval of time in which the knob 5 is not activated, the device 1 automatically returns to the selecting configuration and the value of the parameter set and displayed on the display 8 is stored and/or sent to the control unit 19 of the machine.

In the selecting configuration the operator can select a further operating parameter to be set and by repeating the aforesaid operations is able to assign a value also to the further operating parameter.

Once all the desired operating parameters have been set, the operator, by pressing the start pushbutton 12, starts the machine, for example the wrapping machine 30, which thus performs the functions thereof in the modes previously set by the operator.

1-31. (canceled)

32. Control device that is associable with a wrapping machine, comprising a panel provided with a selecting device for selecting and setting operating parameters of said machine, wherein said selecting device comprises a knob rotatable around an axis and fixed to said panel.

33. Device according to claim 32, wherein said knob is configured so that by rotating around said axis, said knob selects an operating parameter to be set in a selecting mode of said device.

34. Device according to claim 33, wherein said knob is configured so that by rotating around said axis, said knob modifies a value to be assigned to said operating parameter in an adjusting mode of said device.

35. Device according to claim 34, wherein said knob is depressed to confirm the selection of an operating parameter to be set and/or the setting of an adjusted value of said operating parameter.

36. Device according to claim 35, wherein said knob is depressed to move said device from said selecting mode to said adjusting mode and vice versa.

37. Device according to claim 36, wherein said knob is depressed along a direction substantially parallel to said axis.

38. Device according to claim 34, wherein said selecting device comprises a pushbutton arranged for confirming the selection of an operating parameter to be set, in said selecting mode, and/or for confirming an adjusted value of an operating parameter, in said adjusting mode.

39. Device according to claim 32, comprising a display for displaying values of said operating parameters.

40. Device according to claim 32, wherein said panel comprises a plurality of warning lights, each of said warning lights being associated with a respective operating parameter and being activated when said respective operating parameter is selected by said knob.

41. Device according to claim 32, wherein said panel comprises a plurality of display figures, each of said display figures being associated with a respective operating parameter and schematically showing said respective operating parameter.

42. Device according to claim 32, wherein said selecting device comprises a further pushbutton arranged for activating and/or deactivating said machine.

43. Device according to claim 32, and further comprising an electronic control card for supporting and controlling said selecting device.

44. Device according to claim 43, wherein said electronic control card comprises a storage device for storing set values of said operating parameters.

45. Device according to claim 43, wherein said electronic control card is connectable to a control unit for connecting said machine.

46. Device according to claim 45, wherein said electronic control card comprises said control unit.

47. Device according to claim 45, wherein said control unit is an industrial computer.

48. Device according to claim 43, wherein said electronic control card comprises a power card arranged for driving a driving device of said machine.

49. Method for setting operating parameters of a wrapping machine by a control device provided with a knob rotating around an axis, comprising the step of selecting an operating parameter to be set, wherein said selecting step comprises rotating said knob.

50. Method according to claim 49, and further comprising after said selecting step, confirming the selection of said operating parameter to be set.

51. Method according to claim 50, wherein said confirming step comprises moving said control device from a selecting mode for selecting said operating parameters to an adjusting mode for adjusting values of said operating parameters.

52. Method according to claim 50, wherein said confirming step comprises depressing said knob.

53. Method according to claim 50, wherein said confirming step comprises pressing a pushbutton of said control device.

54. Method according to claim 50, wherein after said confirming step the selection of said operating parameter to be set a value to be assigned to said operating parameter to be set is adjusted, said adjusting comprising further rotating said knob.

55. Method according to claim 54, wherein after said adjusting step there is provided the step of further confirming an adjusted value.

56. Method according to claim 55, wherein said further confirming step comprises storing and/or sending to said machine said modified value.

57. Method according to claim 55, wherein said confirming step comprises moving said control device from a selecting mode for selecting said operating parameters to an adjusting mode for adjusting values of said operating parameters and said further confirming step comprises moving said control device from said adjusting mode to said selecting mode.

58. Method according to claim 55, wherein said further confirming step comprises further pressing said pushbutton.

59. Method according to claim 55, said confirming step comprises pressing pushbutton of said control device and wherein said further confirming step comprises further pressing said pushbutton of said control device.

60. Method according to claim 55, wherein said further confirming step is run automatically after a preset interval of time.

61. Control device that is associable with a wrapping machine, comprising a panel provided with a selecting device for selecting and setting operating parameters of said machine and an electronic control card arranged for supporting and controlling said selecting device, wherein said electronic control card comprises a control unit of said machine and a power card arranged for driving a driving device of said machine.

62. Wrapping machine for wrapping a product with a film made of plastics, comprising a control device according to any one of claims 32 to 48 or claim 61.
